(19) United States
(12) Patent Application Publication
(10) Pub. No.: US 2006/0249304 A1
(43) Pub. Date: Nov. 9, 2006

(54) Circuit board and process for producing the same

(76) Inventors: Hideaki Tanaka, Ibaraki (JP); Nobuyuki Sensui, Ibaraki (JP)

Correspondence Address: ALIX YALE & RISTAS LLP, 750 MAIN STREET, SUITE 1400, HARTFORD, CT, 06103, US

(21) Appl. No.: 10/554,660

(22) PCT Filed: Jun. 30, 2004
(86) PCT No.: PCT/JP04/09667

§ 371 Date: Oct. 24, 2005

(30) Foreign Application Priority Data
Jul. 10, 2003 (JP) 2003-195114

(51) Int. Cl. H05K 1/03

(52) U.S. Cl. 174/264; 174/262; 174/255; 29/830; 29/846

(57) ABSTRACT

In the case of using a photosensitive insulating resin for a surface protective layer of a circuit wiring pattern, or for an insulating layer between circuit wiring conductor layers in a circuit board, Na ions adsorbed on the photosensitive insulating resin are replaced with a polyvalent metal through a treatment step containing Na ions which is executed after a heat curing step of the photosensitive insulating resin. For the polyvalent metal, a II group including Mg or Ca can be selected.

### CROSS REFERENCE TO RELATED APPLICATIONS

This application is the national phase of International Application No. PCT/JP2004/009667 which claims the benefit of Japanese Patent Application No. 2003-195114, filed Jul. 10, 2003, the contents of each of which are incorporated herein by reference in their entirety.

### FIELD OF THE INVENTION

The present invention generally relates to a circuit board and its manufacturing method, and more particularly to a circuit board having a surface protective layer and/or an interlayer insulating layer and its manufacturing method.

### BACKGROUND OF THE INVENTION

Miniaturization of the mounted pad portion of circuit boards, for example flexible circuit boards, by miniaturizing mounted components and/or by the high mounting density of components has been a conventional goal of the circuit board industry. These miniaturization efforts have encountered difficulties in the area of, for example, miniaturization by a method of punching and sticking a cover film on the surface of circuit board wiring pattern. Cover film has conventionally been used as a surface protective layer on the surface of the wiring patterns. This cover film is not compatible with the use of small sized components or in conjunction with high mounting density.

An attempt to address the difficulties associated with the cover film has been through the use of a photosensitive insulating resin. This photosensitive insulating resin is applied to a board and is typically subjected to exposure, development, water-washing, and curing steps in order to form a surface protective layer. The use of photosensitive insulating resin has typically resulted in achieving fine opening shapes and complex opening shapes in comparison to methods utilizing the punching and sticking of cover film.

In addition, because of the advantages associated with photosensitive insulating resin, the conventional manufacture of multi-layered circuit boards has made increasing use of photosensitive insulating resin as an interlayer insulating layer.

However, the associated reduction in the weight and thickness of the circuit boards, due to miniaturization, has been accompanied by the problem of substrate bending due to the mismatching of material types in the mainly epoxy or acrylic photosolder resist. This is because the photosolder resist conventionally becomes a hard film, which is easily cracked in the handling of a substrate during the manufacturing process. To avoid these problems, a photosolder resin having a bulky molecular structure and a polymer component such as urethane has been used to form a flexible film.

Conventionally the manufacture of circuit boards having a photosensitive insulating resin surface protective layer and/or a photosensitive insulating resin interlayer comprises forming an insulating film through the steps of coating or laminating a photosensitive insulating resin film on an insulating material base material on which a wiring pattern is present; an exposing step; a developing step; a UV curing; and a heat curing step. Subsequently, a surface treatment, such as plating, may be executed on a mounted pad portion of the circuit board on which the insulating film has been formed.

The conventional development step includes applying an alkali developing solution to the photosensitive insulating resin and then washing the photosensitive insulating resin with water. The developing solution, used in the developing step, is an aqueous solution containing sodium carbonate. The water-washing step, used after the development step, has conventionally been executed by washing with a combination of tap water and purified water.

During the conventional water-washing step Na ions of the sodium carbonate are combined with a carboxyl group present in the insulating resin film in the developing step. The Na ions, among other things, accelerate water absorption into the insulating film during electric conduction tests under high temperature and high humidity. The Na ions then work as an electrolyte thereby reducing insulation performance of the insulating film.

In addition, short-circuiting of the wiring pattern occurs because of dendrite formation. Dendrite formation is caused by the migration and precipitation of ionized copper from an anode side to a cathode side of portions of the board. Furthermore, electrical characteristics and mechanical physical properties may be reduced because the Na ions hydrolyze the molecular chain of the resin under the high temperature and high humidity conditions. This hydrolization of the resin results in a deterioration of the film quality.

Conventionally, Na ions have been removed from the insulating film by washing a circuit board with water containing Ca ions or Mg ions immediately after treatment with the alkali development solution and prior to curing. For example, Japanese Patent Applications Laid-Open No. 2000-208904, 2002-162739, or 2002-305368 disclose treatment immediately after alkali development and prior to curing.

However, during subsequent manufacture of the circuit boards, surface treatments, for example plating, are often carried out following the formation and curing of the insulating resin film. Such treatments typically include an alkali treatment which results in the addition of Na ions to the surfaces. These surface treatments add Na ions by first causing a removal of the Ca ions and/or the Mg ions which had previously been in the water-washing step and second by replacing the removed ions with Na ions present in the surface treatment. For example, Japanese Patent Applications Laid-Open No. 2000-208904, 2002-162739, or 2002-305368, identify problems caused by the replacement of Ca and/or Mg ions with Na ions as described above.

### SUMMARY OF THE INVENTION

Briefly stated, in a preferred form of the invention, a circuit board includes a heat cured photosensitive insulating resin layer. The heat cured layer has a polyvalent metal adsorbed to the heat cured layer at a substantial majority of the sodium adsorption locations. The photosensitive insulating resin is included as a surface protective layer for a circuit wiring pattern and/or as an insulating layer between circuit wiring conductor layers of a multi-layer circuit board. The photosensitive insulating resin, after curing, has adsorption sites for Na ions which are adsorbed to at least one species of polyvalent metal.

The invention also encompasses a method of manufacturing a circuit board which uses a photosensitive insulating resin for a surface protective layer of a circuit wiring pattern and/or an insulating layer between circuit wiring conductor layers of a multilayer circuit board, and includes replacing the adsorbed Na ions on the photosensitive insulating resin with at least one polyvalent metal through a treatment step. The replacement of the Na ions is executed after a heat curing step of the photosensitive insulating resin.

An object of the invention is to alleviate the problem associated with a reduction in environmental resistance caused by water absorption and/or hydrolysis of the insulating resin film, and also to rectify the fragility of the insulating resin film caused by hydrolysis of the resin.

Another object of the invention is to reduce or eliminate the need to use high cost special devices or methods for circuit board manufacture, and to maintain stable developing conditions in order to provide a circuit board which is stable and inexpensive.

### BRIEF DESCRIPTION OF THE DRAWINGS

Other objects and advantages of the invention will be evident to one of ordinary skill in the art from the following detailed description made with reference to the accompanying drawings in which:

FIG. 1 shows a portion of a multi-layer circuit board having a cured photosensitive resin interlayer insulating film consistent with the present invention;

FIG. 2 shows a portion of a circuit board having a cured photosensitive resin protective surface film consistent with the present invention; and

FIG. 3 is a flow chart depicting the steps of creating and treating a cured photosensitive resin protective surface film or interlayer insulating film consistent with the present invention.

### DETAILED DESCRIPTION OF THE PREFERRED EMBODIMENTS

With reference to the drawings wherein like numerals represent like components throughout the figures, a circuit board in accordance with the present invention is designated by the numeral 10. As shown in FIG. 2, the circuit board 10 includes a cured photosensitive layer 12 disposed on the surface of an insulating member 14. The cured photosensitive layer 12 forms a surface protective layer over the insulating member 14 and over a wiring pattern 16. The cured photosensitive layer has a plurality of sodium ion (Na) adsorption sites. The Na adsorption sites include carboxyl groups. A substantial majority of the Na adsorption sites are adsorbed to at least one species of polyvalent metal ion. For example, in one embodiment of the invention the polyvalent metal ion is a group II element. Group II elements have two electrons in their outer electronic shell. For example, group II elements include beryllium, magnesium, calcium, strontium, barium and radium.

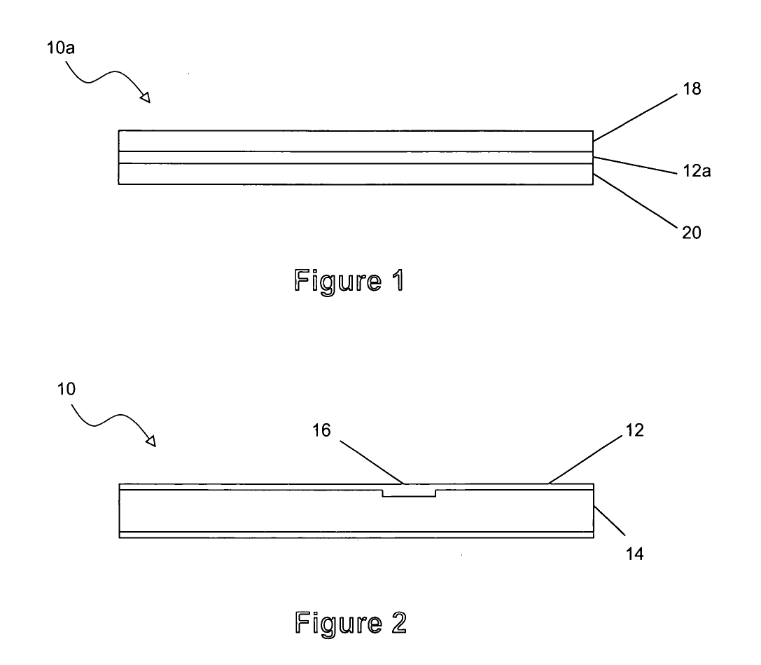

In one embodiment of the invention, the photosensitive insulating layer is an interlayer insulating layer 12a, as shown in FIG. 1. The interlayer insulating layer 12a includes a plurality of Na ion adsorption sites which are substantially adsorbed to at least one polyvalent metal ion. The interlayer insulating layer 12a is positioned between a first insulating member 18 and a second insulating member 20 to form a multi-layer circuit board 10a.

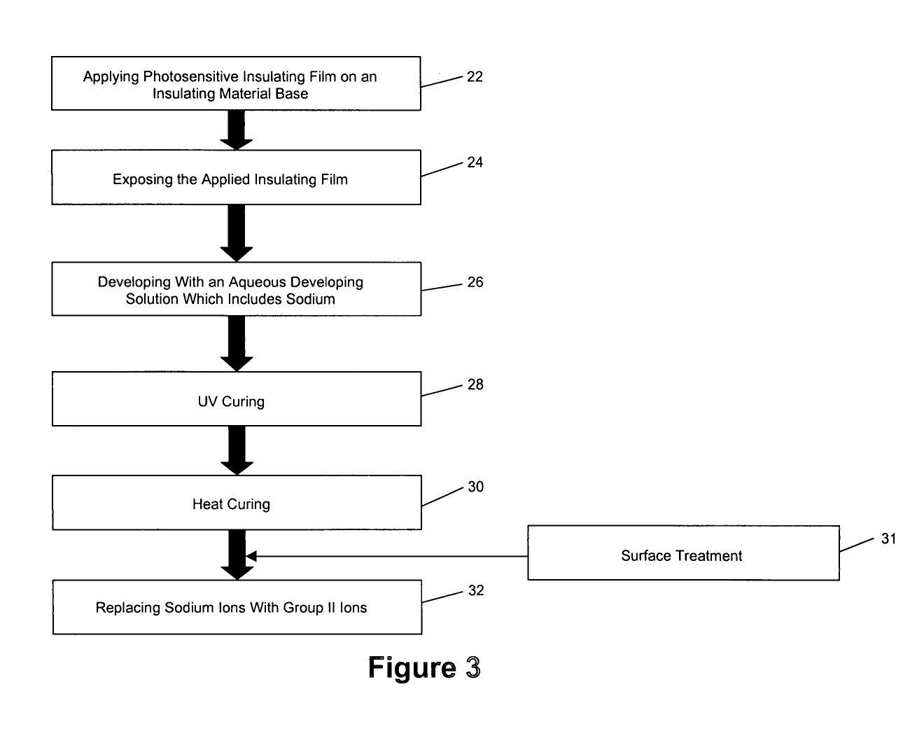

The present invention also encompasses the method of manufacture for a circuit board 10 of the type shown in FIG. 1. In one embodiment of the invention, a wiring pattern 16 is formed on a surface of an insulating member 14. A surface protective layer 12 is then formed on the insulating member 14 and over a surface of the wiring pattern 16. The surface protective layer 12 is formed by first applying, as shown in FIG. 3, a photosensitive insulating layer to the insulating member 22. For example, a photosensitive resin may be coated onto the insulating member or a photosensitive resin material may be laminated to the insulating member. The photosensitive layer is then exposed 24.

After the exposure step 24, a developing step 26 is carried out. The developing step 26 may include applying an alkali developing solution to the coated insulating member. A UV curing step 28 is then carried out, wherein the photosensitive resin is cured with ultraviolet light. A heat curing step 30 is then carried out to form a cured photosensitive insulating layer. After formation of an insulating layer, the circuit board may be subjected to a surface treatment step 31, for example, the circuit board may be plated.

In one embodiment of the present invention, an ion replacement step 32 is carried out. For example, an aqueous ion replacement solution containing Mg ions and/or Ca ions is applied to the circuit board. The aqueous ion replacement solution contains a concentration of Ca and/or Mg ions in the range of about 0.1% by weight to about 10% by weight. Preferably about 0.5 wt % to about 5 wt % of Mg ions and/or Ca ions is present in the ion replacement solution. It should be understood that the ion replacement solution may be used to treat the insulating film after either the heat curing treatment 30 of either the insulating resin film or after the surface treatment 31 of the circuit board. During the ion replacement step 32, Na ions that have adsorbed to the photosensitive insulating resin during the development step 26 and/or the surface treatment step 31 are replaced with Mg and/or Ca ions from the aqueous ion replacement solution. Thus, the Na ions which had combined with a carboxyl group of the Na ions adsorption site during the circuit board manufacturing process are replaced with Mg ions and/or Ca ions. Replacement of the Na ions with the Ca and/or Mg ions, among other things, suppresses water absorption of the photosensitive resin film and hydrolysis of the resin. This allows for an inexpensive and stable flexible circuit board to be produced which has sufficient environmental resistance as provided by a surface protective and/or interlayer insulating layer.

In one embodiment of the invention the photosensitive layer is a negative type ultraviolet cured resin having a film-like photosensitive insulating resin similar in shape to a dry film type resist.

In one embodiment of the invention, the replacement of Na ions with the Mg ions or the Ca ions is carried out after the heat curing step 30 and/or the surface treatment step 31, and/or in conjunction with, a method such as disclosed in Japanese Patent Application Laid-Open No. 2000-208904, 2002-162739, or 2002-305368, used to wash the circuit board with a solution containing Ca ions or Mg ions immediately after alkali development 26.

Various experimental studies have been made with regard to the advantageous concentration of Mg ions or Ca ions in the aqueous ion replacement solution. Experimental results show that a range of 0.1 wt % to 10 wt %, and advantageously a range of 0.5 wt % to 5 wt % of Mg ions or Ca ions advantageously enhance insulating performance; flexibility of the insulating resin film under a high temperature and high humidity; and allow creation of an inexpensive circuit board.

In one experimental test, a circuit board, after a surface treatment that included electrolytic gold plating, was treated with an aqueous ion replacement solution containing 1 wt % of Mg ions. The experimental result after a 1000 hour electrical conduction test showed no reduction in the insulating resistance value of the insulating film as a surface protective layer. There was also no short-circuiting of the wiring pattern in environmental conditions which included a temperature of 85° C. and a relative humidity of 85%. Furthermore, after the plated circuit board was treated with the aqueous ion replacement solution having 1 wt % of Mg ions, a portion of isolated insulating resin film exhibited greater elongation when compared with untreated insulating resin film having no Mg or Ca replacement. The isolated insulating resin film also had a greater comparative flexibility.

While preferred embodiments of the foregoing invention have been set forth for the purposes of illustration, the foregoing description should not be deemed a limitation of the invention herein. Accordingly, various modifications, adaptations and alternatives may occur to one skilled in the art without departing from the spirit and scope of the present invention.

1. A circuit board which uses a photosensitive insulating resin for a surface protective layer of a circuit wiring pattern, characterized in that the photosensitive insulating resin is constituted by replacing Na ions adsorbed thereon with a polyvalent metal through a treatment step containing Na ions which is executed after a heat curing step of the photosensitive insulating resin.

2. A circuit board which uses a photosensitive insulating resin for an insulating layer between circuit wiring conductor layers of a multilayer circuit board, characterized in that the photosensitive insulating resin is constituted by replacing Na ions adsorbed thereon with a polyvalent metal through a treatment step containing Na ions which is executed after a heat curing step of the photosensitive insulting resin.

3. The circuit board according to claim 1, characterized in that the polyvalent metal belongs to a II group.

4. The circuit board according to claim 1, characterized in that the polyvalent metal is Mg or Ca.

5. A method of manufacturing a circuit board which uses a photosensitive insulating resin for a surface protective layer of a circuit wiring pattern, characterized by replacing Na ions adsorbed on the photosensitive insulating resin with a polyvalent metal through a treatment step containing Na ions which is executed after a heat curing step of the photosensitive insulating resin.

6. A method of manufacturing a circuit board which uses a photosensitive insulating resin for an insulating layer between circuit wiring conductor layers of a multilayer circuit board, characterized by replacing Na ions adsorbed on the photosensitive insulating resin with a polyvalent metal through a treatment step containing Na ions which is executed after a heat curing step of the photosensitive insulating resin.

7. The method according to claim 5, characterized in that the polyvalent metal belongs to a II group.

8. The method according to claim 5, characterized in that the polyvalent metal is Mg or Ca.

9. A circuit board comprising:
a heat cured photosensitive insulating resin layer, said heat cured layer having polyvalent metal adsorbed to the heat cured layer at a substantial majority of Na adsorption locations.

10. The circuit of claim 1, wherein the polyvalent metal is a group II element.

11. The circuit of claim 9, wherein the polyvalent metal is Ca.

12. The circuit of claim 9, wherein the polyvalent metal is Mg.

13. The circuit of claim 9, wherein the heat cured layer is a surface protective layer.

14. The circuit of claim 9, wherein the heat cured layer is an insulating layer between circuit wiring conductor layers of a multilayer circuit board.

15. A method of manufacturing a circuit board comprising:
applying a photosensitive insulating resin to the circuit board;
heat curing the photosensitive insulating resin; and
replacing Na ions adsorbed on the photosensitive insulating resin with a polyvalent metal.

16. The method of claim 15, wherein the photosensitive insulating layer is applied as a surface protective layer.

17. The method of claim 15, wherein the photosensitive insulating layer is applied as an insulating layer between circuit wiring conductor layers of a multilayer circuit board.

18. The method of claim 15, wherein the polyvalent metal is a group II element.

19. The method of claim 15, wherein the polyvalent metal is calcium.

20. The method of claim 15, wherein the polyvalent metal is magnesium.
